(19) United States
(12) Patent Application Publication
(10) Pub. No.: US 2011/0156731 A1
(43) Pub. Date: Jun. 30, 2011

(54) SEMICONDUCTOR INTEGRATED CIRCUIT

(76) Inventors: Young-Jun YOON, Gyeonggi-do (KR); Dong-Geum Kang, Gyeonggi-do (KR); Byung-Deuk Jeon, Gyeonggi-do (KR)

(21) Appl. No.: 12/753,378

(22) Filed: Apr. 2, 2010

(30) Foreign Application Priority Data
Dec. 29, 2009 (KR) 10-2009-0133436

(51) Int. Cl. G01R 31/02; G01R 31/3187

(52) U.S. Cl. 324/750.3; 324/755.01

(57) ABSTRACT

A semiconductor integrated circuit includes a first bump pad and a second bump pad configured to perform at least one of a data input operation and a data output operation in a normal mode; a probe pad configured to perform at least one of a data input operation and a data output operation in a test mode; a data output unit configured to communicate a data to one of the first bump pad and the probe pad; a data input unit configured to communicate a data from one of the second bump pad and the probe pad; a first switching unit configured to connect the probe pad and the data output unit in response to a test mode signal; and a second switching unit configured to connect the probe pad and the data input unit in response to the test mode signal.

### CROSS-REFERENCE TO RELATED APPLICATIONS

The present application claims priority of Korean Patent Application No. 10-2009-0133436, filed on Dec. 29, 2009, which is incorporated herein by reference in its entirety.

### BACKGROUND OF THE INVENTION

Exemplary embodiments of the present invention relate to a semiconductor integrated circuit, and more particularly, to a test technology of a semiconductor integrated circuit (IC) having a bump pad.

Recently, technology for fabricating a semiconductor integrated circuit (IC) has been developing to increase an integration rate of a memory cell and to emit heat of the semiconductor IC. However, as the development of packaging technology of the semiconductor IC has lagged behind the development of other technology for fabricating a semiconductor IC, the package technology of the semiconductor IC imposes a limitation on a characteristic of the semiconductor IC.

In order to develop the package technology, various types of packaging methods have been proposed. A chip-on-chip (CoC) package technology is used, which mounts a logic circuit and a memory cell in one package. This chip-on-chip package technology may increase a memory amount, an operating frequency and a signal transmission speed, and reduce total power consumption and the overall area of the semiconductor IC.

Generally, a test operation of the semiconductor IC having bump pads is performed using a bump pad in the chip-on-chip package technology.

However, the bump pad size of the semiconductor IC may become too small to properly perform a probe test on a bump pad in a test mode.

That is, when a bump pad of the semiconductor IC is coupled to external test equipment for the test operation, the bump pad size is too small to couple to the test equipment so that the test operation is not properly performed.

### SUMMARY OF THE INVENTION

An exemplary embodiment of the present invention is directed to a semiconductor IC having a probe pad in a chip-on-chip (CoC) package, capable of optimizing test efficiency for a probe test.

In accordance with an embodiment of the present invention, a semiconductor integrated circuit includes a first bump pad and a second bump pad configured to perform at least one of a data input operation and a data output operation in a normal mode; a probe pad configured to perform at least one of a data input operation and a data output operation in a test mode; a data output unit configured to communicate a data to at least one of the first bump pad and the probe pad; a data input unit configured to communicate a data from at least one of the second bump pad and the probe pad; a first switching unit configured to couple the probe pad and the data output unit in response to a test mode signal; and a second switching unit configured to couple the probe pad and the data input unit in response to the test mode signal.

The first and second switching units may each include one transmission gate, respectively.

The semiconductor integrated circuit may further include a first electro static discharge (ESD) circuit configured to be disposed between the first bump pad and the data output unit; a second electro static discharge (ESD) circuit configured to be disposed between the probe pad and the first and second switching units; and a third electro static discharge (ESD) circuit configured to be disposed between the second bump pad and the data input unit.

The semiconductor IC may be configured such that the test mode signal is activated in a test mode operation, where the probe pad is configured to be coupled to a semiconductor test equipment, or where the probe pad is large enough to accommodate a probe of the semiconductor test equipment.

In accordance with another embodiment of the present invention, a semiconductor integrated circuit includes a data output unit configured to output data from a memory cell to a first bump pad or a probe pad; the first bump pad is configured to output the data from the data output unit to an external system in a normal mode; and the probe pad configured to output the data from the data output unit to an external system in a test mode.

The semiconductor integrated circuit may further include a first switching unit configured to couple the first bump pad and the data output unit in a normal mode and couple the probe pad and the data output unit in a test mode.

In accordance with another embodiment of the present invention, a semiconductor integrated circuit includes a data input unit configured to transmit data from a probe pad or a second bump pad to a memory cell; the second bump pad is configured to transmit the data from external system to the data input unit in a normal mode; and the probe pad is configured to transmit the data from external system to the data input unit in a test mode. The semiconductor integrated circuit may further include a second switching unit configured to couple the second bump pad and the data input unit in a normal mode and couple the probe pad and the data input unit in a test mode.

### BRIEF DESCRIPTION OF THE DRAWINGS

FIG. 1 is a block diagram of semiconductor IC 100 in accordance with a first embodiment of the present invention.

FIG. 2 is a circuit diagram of first and second switching units 160 and 170 referenced in FIG. 1.

FIG. 3 is a block diagram of semiconductor IC 300 in accordance with a second embodiment of the present invention.

### DESCRIPTION OF EXEMPLARY EMBODIMENTS

Exemplary embodiments of the present invention are described below in more detail with reference to the accompanying drawings. The present invention may, however, be embodied in different forms and should not be construed as being limited to the embodiments set forth herein. Rather, these embodiments are provided so that this disclosure will convey the present invention to enable those skilled in the art to practice the invention without undue experimentation. Throughout the disclosure, like reference numerals refer to like parts throughout the various drawing figures and embodiments of the present invention.

A main semiconductor IC will be described below as an example of a semiconductor IC having a chip-on-chip structure. Although the present invention may include any appropriate number of bump pads corresponding to a bit organization, only two bump pads are described within the exemplary embodiment for convenience of explanation.

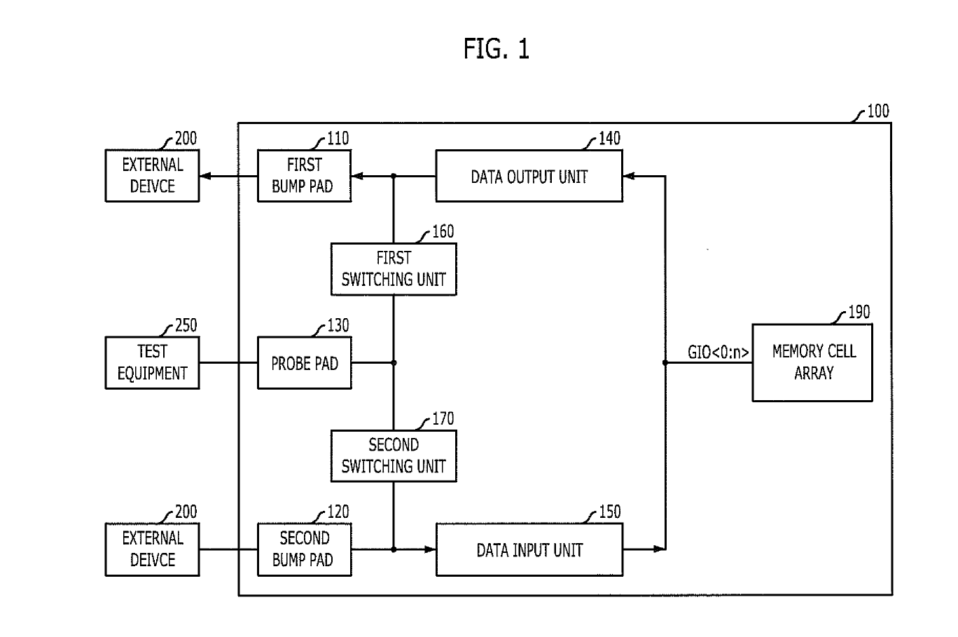

FIG. 1 is a block diagram of a semiconductor integrated circuit (IC) 100 in accordance with a first embodiment of the present invention.

Referring to FIG. 1, the semiconductor IC 100 includes a first bump pad 110, a second bump pad 120, a probe pad 130, a data output unit 140, a data input unit 150, a first switching unit 160, a second switching unit 170 and a memory cell array 190.

The first and second bump pads 110 and 120 include a conductive bump for coupling to an external device 200. The external device may include another semiconductor IC. Generally, a size of the conductive bump is small. For example, a diameter of a micro-bump pad is merely tens of micrometers (μm).

The first bump pad 110 is a data output pad. Data from the memory cell array 190 is output to the external device 200 through the first bump pad 110 during a data output operation of the semiconductor IC 100.

The second bump pad 120 is a data input pad. Data from the external device 200 is input to the semiconductor IC 100 through the second bump pad 120 during a data input operation of the semiconductor IC 100. That is, the first and second bump pads 110 and 120 are disposed to couple the semiconductor IC 100 and the external device 200 and function as a data input/out interface during the data input/output operations of the semiconductor IC 100.

The probe pad 130 may be large enough to accommodate a probe of test equipment 250.

Hereinafter, the data input/output operations between the semiconductor IC 100 and the external device 200 in a normal mode are described in detail.

In the data output operations, the data output unit 140 receives data stored in the memory cell array 190 through a global input/output lines GIO<0:n> and outputs the received data to the external device 200 through the first bump pad 110 in synchronization with data output clocks (not shown).

In the data input operations of the normal mode, the data input unit 150 receives data from the external device 200 through the second bump pad 120 and outputs the received data to the global input/output lines GIO<0:n> to store the received data to the memory cell array 190.

As described above, since the first and second switching units 160 and 170 are turned-off in response to an inactivated test mode signal TM in the normal mode, the probe test pad 130 does not influence to a first data input transmission line and a first data output transmission fine.

The first data input transmission line is formed between the second bump pad 120 and the data input unit 150. The first data output transmission line is formed between the first bump pad 110 and the data output unit 140.

Hereinafter, a test mode operation between the semiconductor IC 100 and the test equipment 250 is described in detail.

A second data input transmission line and a second data output transmission line are enabled by turning on the first and second switching units 160 and 170 in response to an activated test mode signal TM in a test mode. The second data output transmission line is formed between the probe test pad 130 and the data output unit 140. The second data input transmission line is formed between the probe test pad 130 and the data input unit 150.

After enabling the second data input/output transmission lines, the data input/output operations between the semiconductor IC 100 and test equipment 250 are performed for a test operation when the probe test pad 130 is coupled to the test equipment 250. That is, the test operation is performed between the semiconductor IC 100 and the test equipment 250.

Referring to FIG. 1, one of the probe test pad 130 and the first and second bump pads 110 and 120 is selectively used as data input/output pads according to whether the semiconductor IC 100 is operating in the normal mode or the test mode.

Reliability of the data input/output operation is secured by suppressing an interference of the probe test pad 130, an interference of the first data input transmission line in the data output operation and the first data output transmission line in the data input operation when the first and second bump pads 110 and 120 are coupled to another data transmission line separated from the probe test pad 130 to perform the data input/output operations in the regular mode and not the test operation.

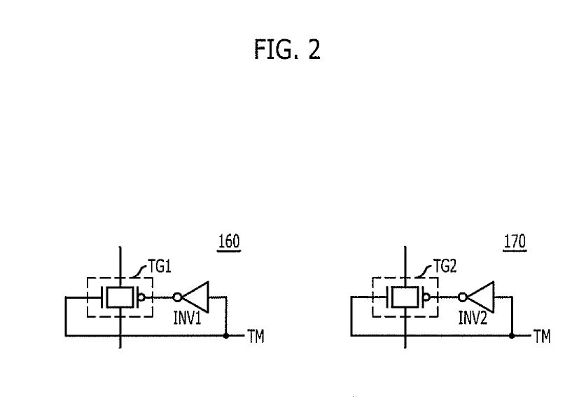

FIG. 2 is a block diagram of the first and second switching unit 160 and 170.

Referring to FIG. 2, the first switching unit 160 includes a first transmission gate TG1 and a first inverter INV1. The first transmission gate TG1 is turned-on/off in response to an output of first inverter INV1. The first inverter INV1 controls the first transmission gate TG1 in response to the test mode signal TM.

The second switching unit 170 includes a second transmission gate TG2 and a second inverter INV2. The second transmission gate TG2 is turned-on/off in response to an output of second inverter INV2. The second inverter INV2 controls the second transmission gate TG2 in response to the test mode signal TM.

The test mode signal TM is activated prior to starting the test mode operation.

The first and second transmission gates TG1 and TG2 are turned-on to enable the second data input/output transmission lines when the test mode signal TM is activated.

Since the first and second switching unit 160 and 170 respectively include one transmission gate and one inverter, delay of the test mode signal TM is minimized and an area occupying the first and second switching unit 160 and 170 has been reduced.

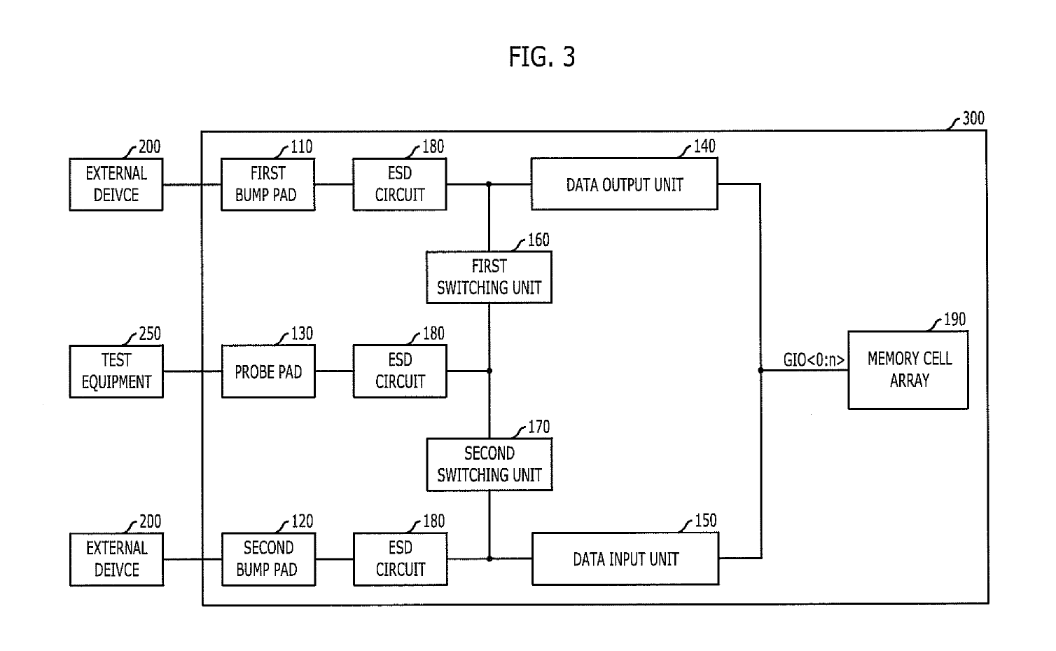

FIG. 3 is a block diagram of a semiconductor IC 300 in accordance with a second embodiment of the present invention.

Referring to FIG. 3, the semiconductor IC 300 includes the first bump pad 110, the second bump pad 120, the probe pad 130, the data output unit 140, the data input unit 150, the first switching unit 160, the second switching unit 170 and the memory cell array 190.

The semiconductor IC 300 Shown in FIG. 3 further includes an electro static discharge (ESD) circuit 180 disposed between the first bump pad 110 and the data output unit 140, between the probe pad 130 and the first and second switching units 160 and 170 and between the second bump pad 120 and the data input unit 150.

An electro static discharge (ESD) is a discharging phenomenon by a static electricity. At this time, the semiconductor IC may be damaged if static electricity is introduced through an input pin of the semiconductor IC by an over-flowed current according to the electro static discharge (ESD). For example, when a person touches a pin of the semiconductor IC with his/her hands or a test device, a small amount of charges may be transferred through the input pin the semiconductor IC to the first and second bump pads 110 and 120 or the probe test pad 130 provided inside the semiconductor IC. Since the input pin has a very small capacitance, a voltage of static electricity transferred through the input pin can be higher.

Consequently, there is a need for the semiconductor IC designs which can protect the semiconductor ICs from static electricity introduced the first and second bump pads 110 and 120 or the probe test pad 130 provided inside the semiconductor ICs.

Accordingly, in exemplary embodiments of the present invention provides the ESD circuits to prevent the semiconductor IC 300 from being damaged.

In the semiconductor IC in accordance with the exemplary embodiments of the present invention may be tested in a wafer level using the probe test pad 130 and minimize a mutual interference between the first data input/output transmission lines and the second data input/output transmission lines during data input/output operations. In particular, since the net yield or gross die of a wafer may be increased by improving an arrangement of the entire chip area of the semiconductor IC, it is possible to reduce a production cost of the semiconductor IC.

While the present invention has been described with respect to specific embodiments, it will be apparent to those skilled in the art that various changes and modifications may be made without departing from the spirit and scope of the present invention as defined by the following claims.

What is claimed is:

1. A semiconductor integrated circuit, comprising:
a first bump pad and a second bump pad configured to perform at least one of a data input operation and a data output operation in a normal mode;
a probe pad configured to perform at least one of a data input operation and a data output operation in a test mode;
a data output unit configured to communicate a data to at least one of the first bump pad and the probe pad;
a data input unit configured to communicate a data from at least one of the second bump pad and the probe pad;
a first switching unit configured to couple the probe pad and the data output unit in response to a test mode signal; and
a second switching unit configured to couple the probe pad and the data input unit in response to the test mode signal.

2. The semiconductor integrated circuit of claim 1, wherein the first and second switching units comprise one transmission gate, respectively.

3. The semiconductor integrated circuit of claim 1, further comprising:
a first electro static discharge circuit configured to be disposed between the first bump pad and the data output unit;
a second electro static discharge circuit configured to be disposed between the probe pad and the first and second switching units; and
a third electro static discharge circuit configured to be disposed between the second bump pad and the data input unit.

4. The semiconductor integrated circuit of claim 1, wherein the test mode signal is activated in a test mode operation.

5. The semiconductor integrated circuit of claim 1, wherein the probe pad is configured to be coupled to a semiconductor test equipment.

6. The semiconductor integrated circuit of claim 5, wherein the probe pad is large enough to accommodate a probe of the semiconductor test equipment.

7. The semiconductor integrated circuit of claim 5, wherein the first bump pad and the second bump pad are configured to be coupled to an external device.

8. The semiconductor integrated circuit of claim 7, wherein the test equipment and the external device are included in one system.
